(19) United States
(12) Patent Application Publication
(10) Pub. No.: US 2025/0015210 A1
(43) Pub. Date: Jan. 9, 2025

(54) INTEGRATED STRUCTURE OF WAVEGUIDE AND ACTIVE COMPONENT AND MANUFACTURING METHOD THEREOF

(71) Applicant: NATIONAL TSING HUA UNIVERSITY, HSINCHU (TW)

(72) Inventor: Ming-Chang LEE, Hsinchu City (TW)

(21) Appl. No.: 18/234,788

(22) Filed: Aug. 16, 2023

(30) Foreign Application Priority Data
Jul. 3, 2023 (TW) 112124799

(51) Int. Cl. H01L 31/0232; G02B 6/125; G02B 6/132; G02B 6/136; H01L 31/02; H01L 31/0203; H01L 31/18

(52) U.S. Cl. CPC H01L 31/02325; G02B 6/125; G02B 6/132; G02B 6/136; H01L 31/02005; H01L 31/0203; H01L 31/1812; H01L 31/1864; G02B 2006/12038; G02B 2006/12173; G02B 2006/12188; G02B 2006/12197

(57) ABSTRACT

A manufacturing method for an integrated structure of a waveguide and an active component is proposed. The manufacturing method includes providing a substrate including a dielectric layer and a semiconductor layer, and the semiconductor layer includes a waveguide region, a transition region and an active component region; etching the semiconductor layer to form a plurality of waveguide trenches; depositing a waveguide material on the semiconductor layer to form a deposition layer, and the waveguide trenches are filled with the waveguide material; performing an ion implantation process on the semiconductor layer to form a first doped portion and a second doped portion; etching the waveguide region, the transition region and the active component region to form a waveguide structure, a transition structure and an active component structure; depositing a cover layer on the dielectric layer; forming two via holes and two contact pads in the cover layer.

### RELATED APPLICATIONS

This application claims priority to Taiwan Application Serial Number 112124799, filed Jul. 3, 2023, which is herein incorporated by reference.

### BACKGROUND

### Technical Field

The present disclosure relates to an integrated structure of a waveguide and an active component and a manufacturing method thereof. More particularly, the present disclosure relates to an integrated structure of a silicon nitride waveguide and a semiconductor active component and a manufacturing method thereof.

### Description of Related Art

Integrated photonics platforms based on silicon nitride waveguides have attracted considerable attention in recent years. The main reason is that these platforms can be implemented via advanced semiconductor manufacturing processes and are potential for mass production. Among them, the platform with low-loss and anomalous-dispersion silicon nitride waveguides has received special attention. This type of waveguide is an important component for the development of nonlinear integrated optics and requires a thick-film waveguide structure. However, to make the waveguides low-loss and anomalous-dispersion, integration with other semiconductor active components becomes very difficult, resulting in many limitations in application.

The existing waveguide manufacturing methods are divided into two types. One is to deposit thick silicon nitride first, and then use an etching process to directly form a waveguide structure on the thick silicon nitride. The other is to deposit a thick silicon dioxide (i.e., optical cladding material) and etch trenches to define the positions of the silicon nitride waveguides, and then fill the trench with silicon nitride by a deposition process. Later a planarization process is applied to removes excess silicon nitride, just like embedding silicon nitride into the pre-defined trenches. The silicon nitride waveguide produced by the former has a large optical loss due to rough side walls. Although the latter can use thermal reflow to smoothen the sidewall roughness to reduce the optical loss of the subsequently formed silicon nitride waveguide, the above two waveguide manufacturing methods are very difficult to monolithically integrate with semiconductor photodetectors, due to the high aspect ratio of waveguide structure. In view of this, the market lacks an integrated structure of silicon nitride waveguide and semiconductor active components and a manufacturing method thereof that can solve the abovementioned problems, and thus this is an issue to be resolved by the related industry.

### SUMMARY

According to one aspect of the present disclosure, an integrated structure of a waveguide and an active component includes a dielectric layer, a waveguide structure, a transition structure, an active component structure, a cover layer, two via holes and two contact pads. The waveguide structure is disposed on the dielectric layer. The transition structure is disposed on the dielectric layer and connected to the waveguide structure. The active component structure is disposed on the dielectric layer and connected to the transition structure. The cover layer is disposed on the dielectric layer and covers the waveguide structure, the transition structure and the active component structure. The two via holes are located in the cover layer and connected to the active component structure. The two contact pads are located in the cover layer and respectively disposed on the two via holes.

According to another aspect of the present disclosure, a manufacturing method of an integrated structure of a waveguide and an active component includes performing a substrate providing step, a trench forming step, a waveguide depositing step, a deposition layer polishing step, an ion implanting step, a semiconductor layer etching step, a cover layer depositing step and a via hole and contact pad forming step. The substrate providing step includes providing a substrate, wherein the substrate includes a dielectric layer and a semiconductor layer disposed on the dielectric layer, and the semiconductor layer includes a waveguide region, a transition region and an active component region. The trench forming step includes etching the semiconductor layer to form a plurality of waveguide trenches in the waveguide region and the transition region of the semiconductor layer. The waveguide depositing step includes depositing a waveguide material on the semiconductor layer to form a deposition layer on the semiconductor layer, wherein the waveguide trenches are filled with the waveguide material. The deposition layer polishing step includes performing a chemical-mechanical polishing process on the deposition layer to expose a surface in the semiconductor layer and the waveguide material filled in the waveguide trenches. The ion implanting step includes performing an ion implantation process on the semiconductor layer to form a first doped portion and a second doped portion in the active component region. The semiconductor layer etching step includes etching the waveguide region to form a waveguide structure; etching the transition region to form a transition structure; and etching the first doped portion and the second doped portion to form an active component structure. The cover layer depositing step includes depositing a cover layer on the dielectric layer, wherein the cover layer covers the waveguide structure, the transition structure and the active component structure. The via hole and contact pad forming step includes forming two via holes connected to the active component structure in the cover layer, and respectively forming two contact pads on the two via holes.

### BRIEF DESCRIPTION OF THE DRAWINGS

The present disclosure can be more fully understood by reading the following detailed description of the embodiment, with reference made to the accompanying drawings as follows:

FIG. 1 shows a top view of an integrated structure of a waveguide and an active component after transparentizing a dielectric layer and a cover layer according to a first embodiment of the present disclosure.

FIG. 2 is a cross-sectional view of the integrated structure of the waveguide and the active component along a plurality of tangent lines of FIG. 1.

FIG. 3 shows a flow chart of a manufacturing method of the integrated structure of the waveguide and the active component according to a second embodiment of the present disclosure.

FIG. 4 shows a flow chart of a trench forming step in FIG. 3.

FIG. 5 shows a flow chart of a semiconductor layer etching step in FIG. 3.

FIG. 6 shows a flow chart of a mask disposing step in FIG. 5.

FIG. 7A shows a cross-sectional view of a substrate providing step of the manufacturing method of the second embodiment.

FIG. 7B shows a cross-sectional view of the trench forming step of the manufacturing method of the second embodiment.

FIG. 7C shows a cross-sectional view of a waveguide depositing step of the manufacturing method of the second embodiment.

FIG. 7D shows a cross-sectional view of a deposition layer polishing step of the manufacturing method of the second embodiment.

FIG. 7E shows a cross-sectional view of an ion implanting step of the manufacturing method of the second embodiment.

FIG. 7F shows a cross-sectional view of a mask depositing step of the mask disposing step of the semiconductor layer etching step of the manufacturing method of the second embodiment.

FIG. 7G shows a cross-sectional view of a photolithography step and a mask etching step of the mask disposing step of the semiconductor layer etching step of the manufacturing method of the second embodiment.

FIG. 7H shows a cross-sectional view of a first etching step of the semiconductor layer etching step of the manufacturing method of the second embodiment.

FIG. 7I shows a cross-sectional view of a first photoresist forming step of the semiconductor layer etching step of the manufacturing method of the second embodiment.

FIG. 7J shows a cross-sectional view of a second etching step of the semiconductor layer etching step of the manufacturing method of the second embodiment.

FIG. 7K shows a cross-sectional view of removing a hard mask in a second photoresist forming step of the semiconductor layer etching step of the manufacturing method of the second embodiment.

FIG. 7L shows a cross-sectional view of forming a photoresist in the second photoresist forming step of the semiconductor layer etching step of the manufacturing method of the second embodiment.

FIG. 7M shows a cross-sectional view of a third etching step of the semiconductor layer etching step of the manufacturing method of the second embodiment.

FIG. 7N shows a cross-sectional view of a cover layer depositing step of the manufacturing method of the second embodiment.

FIG. 7O shows a cross-sectional view of a via hole and contact pad forming step of the manufacturing method of the second embodiment.

FIG. 7P shows another cross-sectional view of the via hole and contact pad forming step of the manufacturing method of the second embodiment.

FIG. 7Q shows yet another cross-sectional view of the via hole and contact pad forming step of the manufacturing method of the second embodiment.

FIG. 8 shows a flow chart of a semiconductor layer etching step of a manufacturing method of the integrated structure of the waveguide and the active component according to a third embodiment of the present disclosure.

FIG. 9A is a cross-sectional view of a mask disposing step of the semiconductor layer etching step of the manufacturing method according to the third embodiment of the present disclosure.

FIG. 9B shows a cross-sectional view of a first photoresist forming step of the semiconductor layer etching step of the manufacturing method of the third embodiment.

FIG. 9C shows a cross-sectional view of a first etching step of the semiconductor layer etching step of the manufacturing method of the third embodiment.

FIG. 9D shows a cross-sectional view of a second photoresist forming step of the semiconductor layer etching step of the manufacturing method of the third embodiment.

FIG. 9E shows a cross-sectional view of a second etching step of the semiconductor layer etching step of the manufacturing method of the third embodiment.

FIG. 9F shows a cross-sectional view of removing a photoresist and a hard mask in a removing step of the semiconductor layer etching step of the manufacturing method of the third embodiment.

FIG. 9G shows a cross-sectional view of a third photoresist forming step of the semiconductor layer etching step of the manufacturing method of the third embodiment.

FIG. 9H shows a cross-sectional view of a third etching step of the semiconductor layer etching step of the manufacturing method of the third embodiment.

FIG. 9I shows another cross-sectional view of the third etching step of the semiconductor layer etching step of the manufacturing method of the third embodiment.

### DETAILED DESCRIPTION

The embodiment will be described with the drawings. For clarity, some practical details will be described below. However, it should be noted that the present disclosure should not be limited by the practical details, that is, in some embodiment, the practical details is unnecessary. In addition, for simplifying the drawings, some conventional structures and elements will be simply illustrated, and repeated elements may be represented by the same labels.

It will be understood that when an element (or device) is referred to as be “connected” to another element, it can be directly connected to the other element, or it can be indirectly connected to the other element, that is, intervening elements may be present. In contrast, when an element is referred to as be “directly connected to” another element, there are no intervening elements present. In addition, the terms first, second, third, etc. are used herein to describe various elements or components, these elements or components should not be limited by these terms. Consequently, a first element or component discussed below could be termed a second element or component.

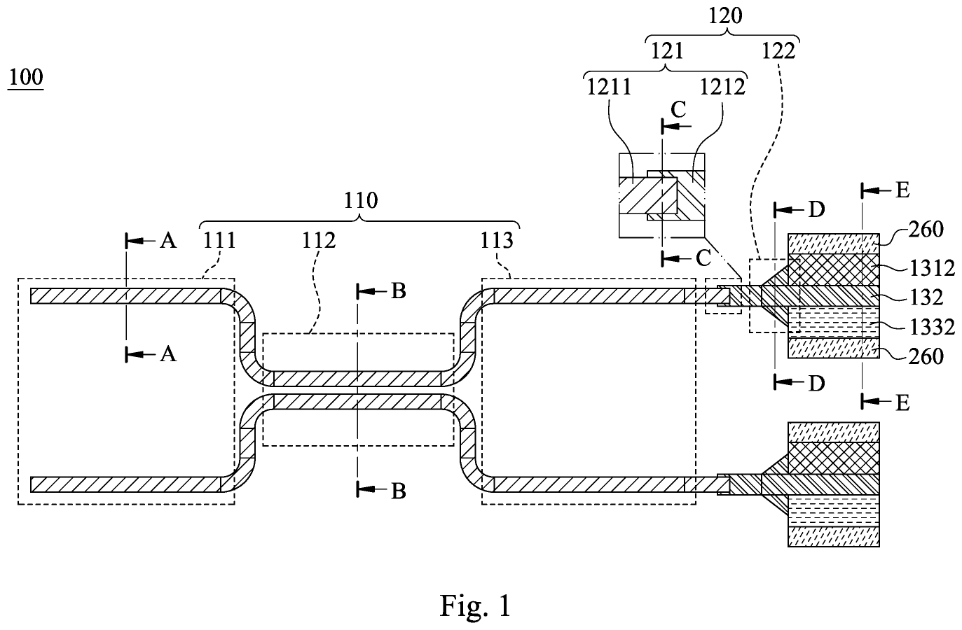

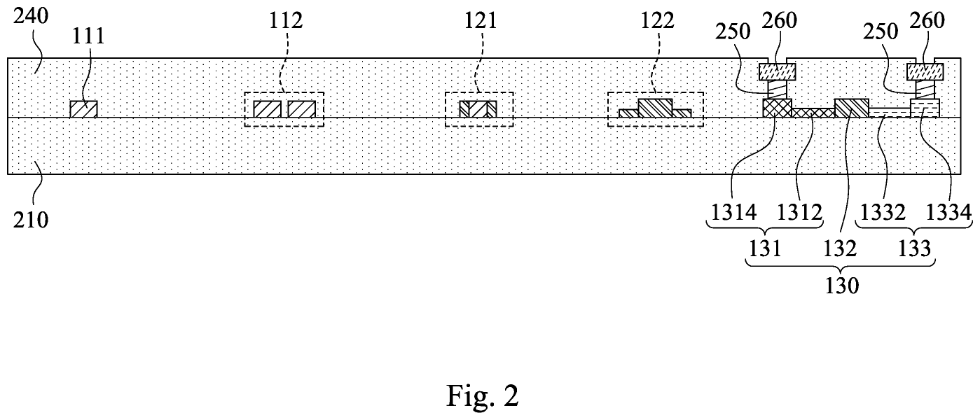

Please refer to FIGS. 1 and 2. FIG. 1 shows a top view of an integrated structure 100 of a waveguide and an active component after transparentizing a dielectric layer 210 and a cover layer 240 according to a first embodiment of the present disclosure. FIG. 2 is a cross-sectional view of the integrated structure 100 of the waveguide and the active component along a plurality of tangent lines A-A, B-B, C-C, D-D, E-E of FIG. 1. In FIGS. 1 and 2, the integrated structure 100 of the waveguide and the active component includes a dielectric layer 210, a waveguide structure 110, a transition structure 120, an active component structure 130, a cover layer 240, two via holes 250 and two contact pads 260. The waveguide structure 110 is disposed on the dielectric layer 210. The transition structure 120 is disposed on the dielectric layer 210 and connected to the waveguide structure 110. The active component structure 130 is disposed on the dielectric layer 210 and connected to the transition structure 120. The cover layer 240 is disposed on the dielectric layer 210 and covers the waveguide structure 110, the transition structure 120 and the active component structure 130. The two via holes 250 are located in the cover layer 240 and connected to the active component structure 130. The two contact pads 260 are located in the cover layer 240 and respectively disposed on the two via holes 250.

A material of the dielectric layer 210 and the cover layer 240 can be a low dielectric constant material, a high dielectric constant material or other optical cladding materials, and the present disclosure uses silicon dioxide (SiO₂) as the material of the dielectric layer 210 and the cover layer 240. The waveguide structure 110 is composed of a waveguide material, and the waveguide material can be silicon (Si), silicon nitride (SiN), silicon oxide nitride (SiON) or silicon carbide (SiC), and the present disclosure uses silicon nitride (Si₃N₄) as the waveguide material.

In particular, the waveguide structure 110, the transition structure 120 and the active component structure 130 are in the cover layer 240 and disposed on the dielectric layer 210. The waveguide structure 110, the transition structure 120 and the active component structure 130 are disposed between the dielectric layer 210 and the cover layer 240, and connected to each other in sequence. The waveguide structure 110 can include a first waveguide portion 111, a directional coupling portion 112 and a second waveguide portion 113. The directional coupling portion 112 is connected between the first waveguide portion 111 and the second waveguide portion 113. Based on the directional coupling portion 112 as a center, the first waveguide portion 111 and the second waveguide portion 113 are disposed symmetrically to each other and respectively connected to the directional coupling portion 112 on both sides. The first waveguide portion 111 and the second waveguide portion 113 are configured to propagate optical signals or energy of light wave, and the directional coupling portion 112 is configured to couple the optical signals or the energy of light wave from one waveguide to the other waveguide.

The transition structure 120 can include a first transition portion 121 and a second transition portion 122. The first transition portion 121 can include a waveguide connecting sub-portion 1211 and a semiconductor connecting sub-portion 1212. One end of the waveguide connecting sub-portion 1211 is connected to the second waveguide portion 113 of the waveguide structure 110. The semiconductor connecting sub-portion 1212 is connected to and surrounds another end of the waveguide connecting sub-portion 1211. The second transition portion 122 is connected between the semiconductor connecting sub-portion 1212 and the active component structure 130, and a cross section of the second transition portion 122 is formed in a protruded shape so as to improve a light coupling efficiency of an optical signal transmitted from the waveguide structure 110 to the active component structure 130. In addition, the waveguide connecting sub-portion 1211 is composed of silicon nitride (Si₃N₄), and the semiconductor connecting sub-portion 1212 and the second transition portion 122 are both composed of silicon (Si), but the present disclosure is not limited thereto.

The active component structure 130 is configured with the two via holes 250 and the two contact pads 260 after a back-end process of packaging and testing, so that the active component structure 130, the two via holes 250 and the two contact pads 260 can be used as a photodetector or a photodiode. The active component structure 130 can include a first doped portion 131, a semiconductor portion 132 and a second doped portion 133, and the first doped portion 131, the semiconductor portion 132 and the second doped portion 133 are directly connected to the second transition portion 122. The semiconductor portion 132 is connected between the first doped portion 131 and the second doped portion 133. The first doped portion 131 can be formed by performing an ion implantation process or a thermal diffusion process to dope a semiconductor material with a P-type dopant (such as boron (B)), and used as a P-type well. Similarly, the second doped portion 133 can be formed by performing the ion implantation process or the thermal diffusion process to dope a semiconductor material with an N-type dopant (such as phosphorus (P) or arsenic (As)), and used as an N-type well. In addition, the first doped portion 131 can include a P-type region 1312 and a heavily doped P-type (P+) region 1314. The second doped portion 133 can include an N-type region 1332 and a heavily doped N-type (N+) region 1334. The heavily doped P-type region 1314 and the heavily doped N-type region 1334 are mainly used as electrical contact regions of the photodetectors or the photodiode.

Therefore, the integrated structure 100 of the waveguide and the active component of the present disclosure connects the waveguide structure 110 and the active component structure 130 through the transition structure 120. The waveguide structure 110, the transition structure 120 and the active component structure 130 are disposed on the dielectric layer 210, and located in the cover layer 240, thereby improving the light coupling efficiency between the silicon nitride waveguide with low-loss and anomalous-dispersion and the semiconductor active component. Thus, the integrated structure 100 of the waveguide and the active component can be applied to low-loss photonic integrated circuits, visible photonic integrated circuits and nonlinear optical resonance cavities. A method for manufacturing the integrated structure 100 of the waveguide and the active component is described in more detail with the drawings below.

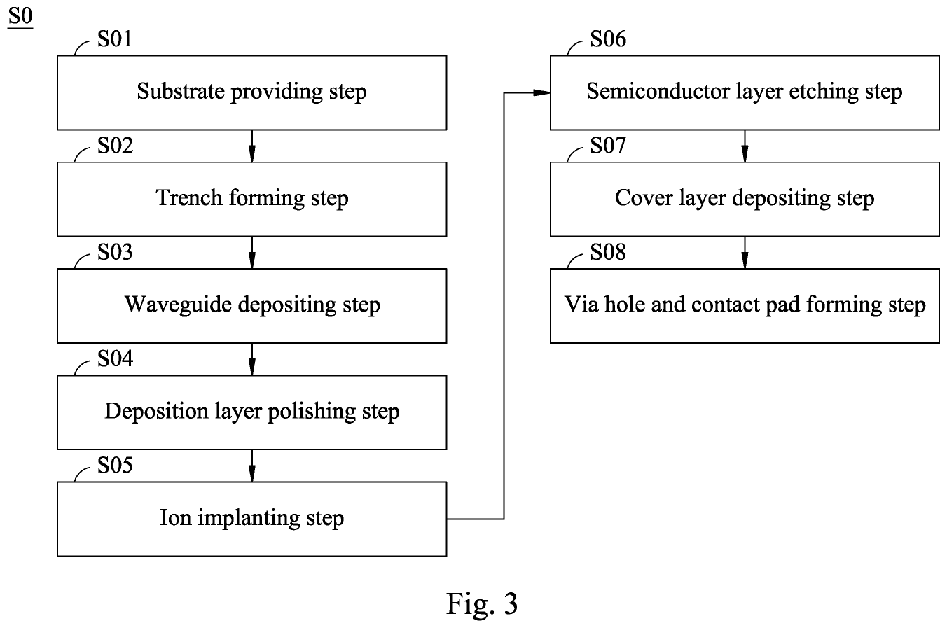

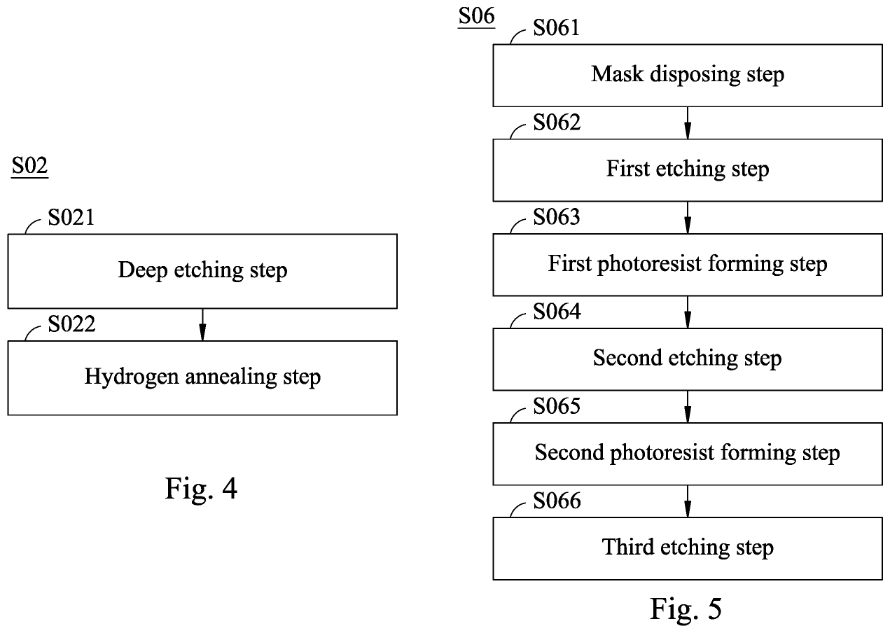

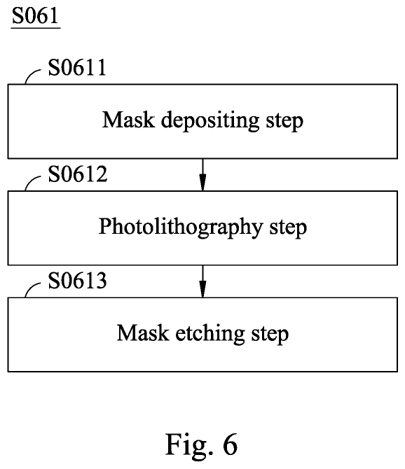

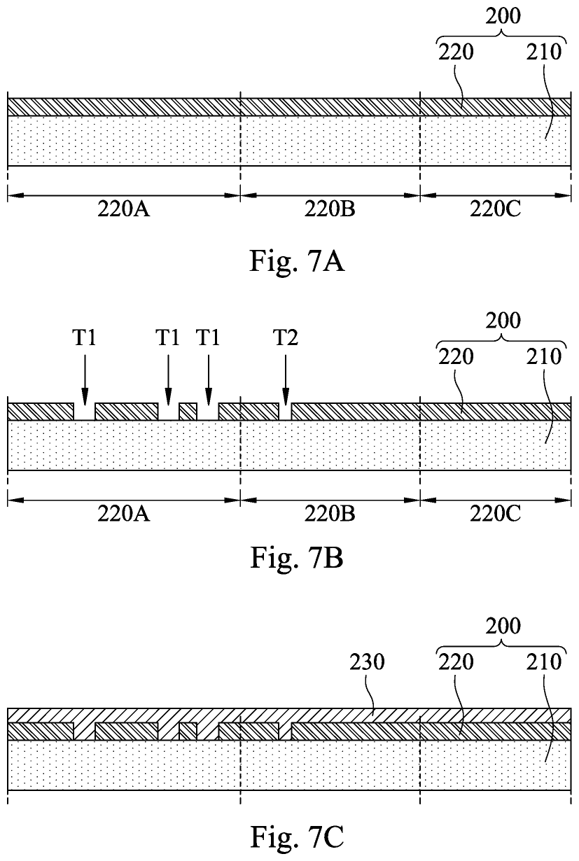

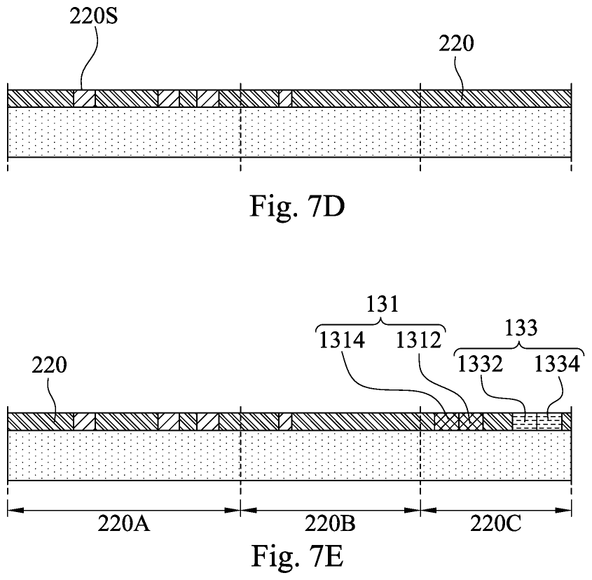

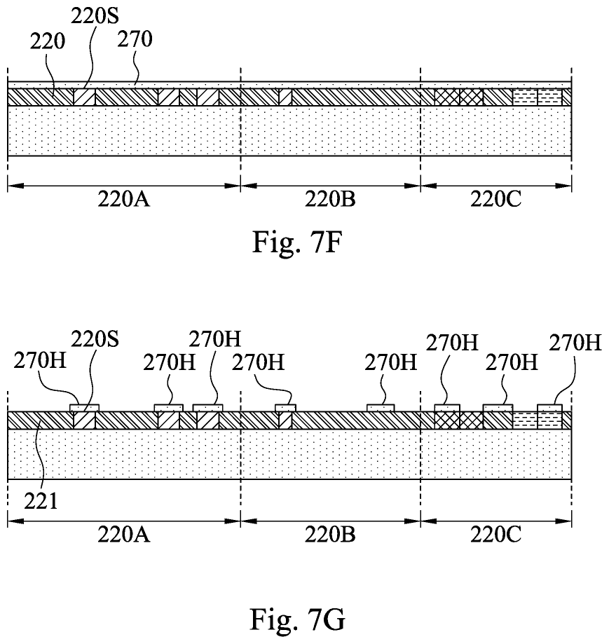

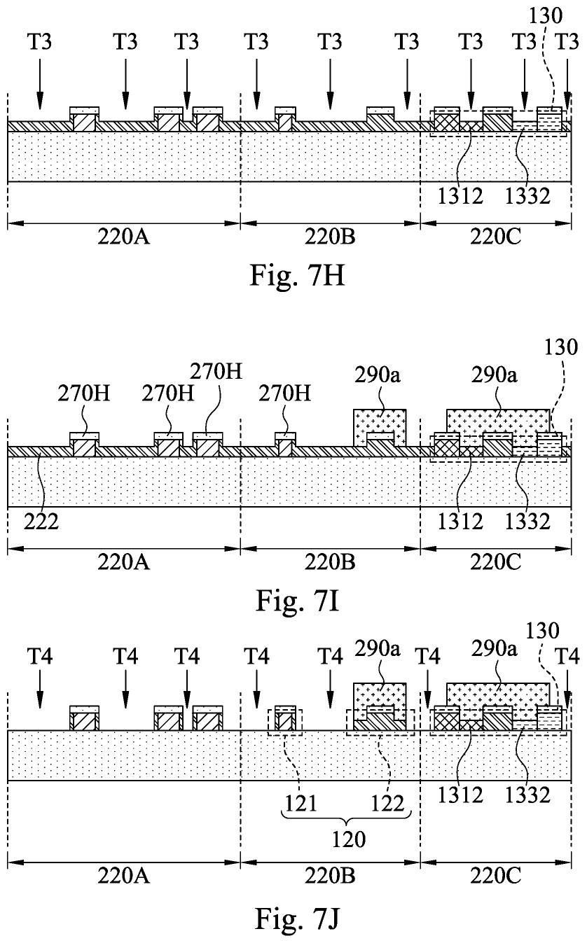

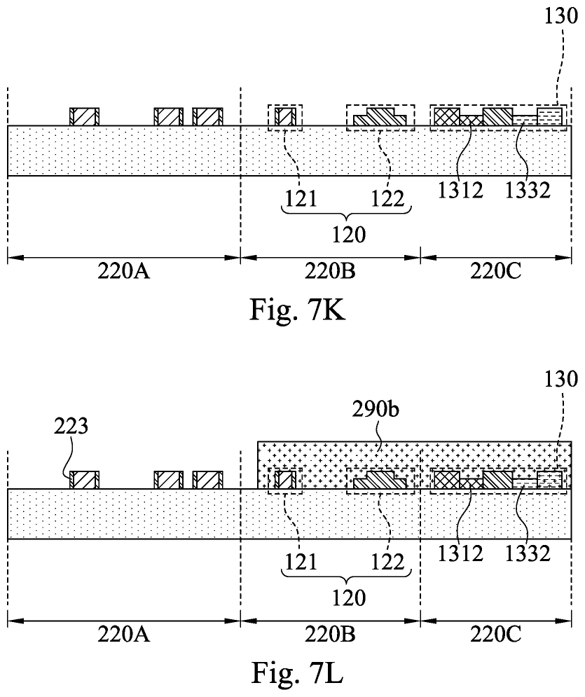

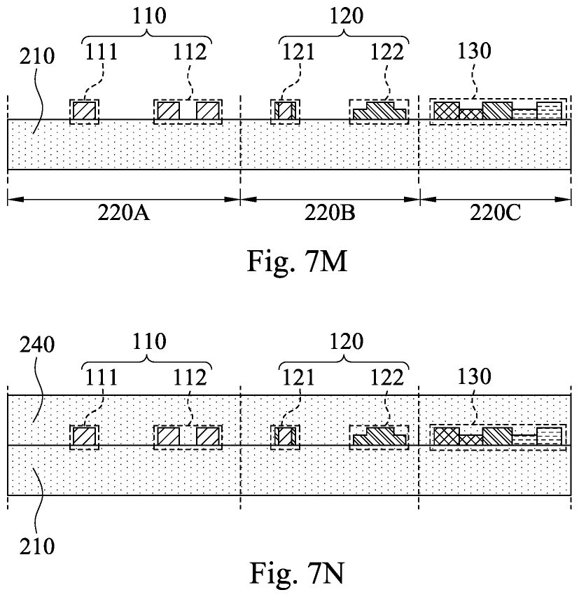

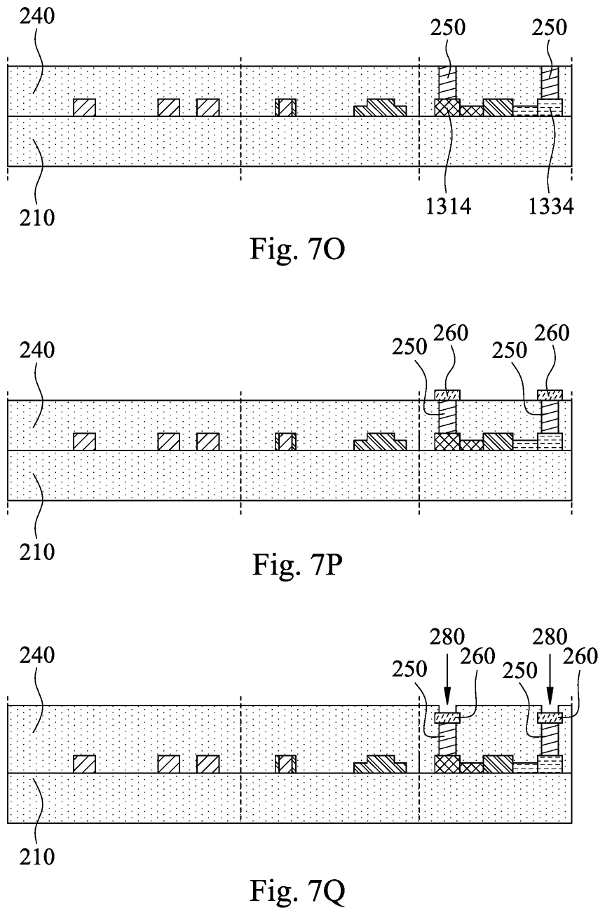

Please refer to FIGS. 1, 3, 4, 5, 6, 7A, 7B, 7C, 7D, 7E, 7F, 7G, 7H, 7I, 7J, 7K, 7L, 7M, 7N, 7O, 7P and 7Q. FIG. 3 shows a flow chart of a manufacturing method S0 of the integrated structure of the waveguide and the active component (hereinafter referred to as the manufacturing method S0) according to a second embodiment of the present disclosure. FIG. 4 shows a flow chart of a trench forming step S02 in FIG. 3. FIG. 5 shows a flow chart of a semiconductor layer etching step S06 in FIG. 3. FIG. 6 shows a flow chart of a mask disposing step S061 in FIG. 5. FIG. 7A shows a cross-sectional view of a substrate providing step S01 of the manufacturing method S0 of the second embodiment. FIG. 7B shows a cross-sectional view of the trench forming step S02 of the manufacturing method S0 of the second embodiment. FIG. 7C shows a cross-sectional view of a waveguide depositing step S03 of the manufacturing method S0 of the second embodiment. FIG. 7D shows a cross-sectional view of a deposition layer polishing step S04 of the manufacturing method S0 of the second embodiment. FIG. 7E shows a cross-sectional view of an ion implanting step S05 of the manufacturing method S0 of the second embodiment. FIG. 7F shows a cross-sectional view of a mask depositing step S0611 of the mask disposing step S061 of the semiconductor layer etching step S06 of the manufacturing method S0 of the second embodiment. FIG. 7G shows a cross-sectional view of a photolithography step S0612 and a mask etching step S0613 of the mask disposing step S061 of the semiconductor layer etching step S06 of the manufacturing method S0 of the second embodiment. FIG. 7H shows a cross-sectional view of a first etching step S062 of the semiconductor layer etching step S06 of the manufacturing method S0 of the second embodiment. FIG. 7I shows a cross-sectional view of a first photoresist forming step S063 of the semiconductor layer etching step S06 of the manufacturing method S0 of the second embodiment. FIG. 7J shows a cross-sectional view of a second etching step S064 of the semiconductor layer etching step S06 of the manufacturing method S0 of the second embodiment. FIG. 7K shows a cross-sectional view of removing a hard mask in a second photoresist forming step S065 of the semiconductor layer etching step S06 of the manufacturing method S0 of the second embodiment. FIG. 7L shows a cross-sectional view of forming a photoresist in the second photoresist forming step S065 of the semiconductor layer etching step S06 of the manufacturing method S0 of the second embodiment. FIG. 7M shows a cross-sectional view of a third etching step S066 of the semiconductor layer etching step S06 of the manufacturing method S0 of the second embodiment. FIG. 7N shows a cross-sectional view of a cover layer depositing step S07 of the manufacturing method S0 of the second embodiment. FIG. 7O shows a cross-sectional view of a via hole and contact pad forming step S08 of the manufacturing method S0 of the second embodiment. FIG. 7P shows another cross-sectional view of the via hole and contact pad forming step S08 of the manufacturing method S0 of the second embodiment. FIG. 7Q shows yet another cross-sectional view of the via hole and contact pad forming step S08 of the manufacturing method S0 of the second embodiment.

The manufacturing method S0 of the present disclosure includes performing a substrate providing step S01, a trench forming step S02, a waveguide depositing step S03, a deposition layer polishing step S04, an ion implanting step S05, a semiconductor layer etching step S06, a cover layer depositing step S07 and a via hole and contact pad forming step S08.

As shown in FIGS. 3 and 7A, the substrate providing step S01 includes providing a substrate 200. The substrate 200 includes the dielectric layer 210 and the semiconductor layer 220 disposed on the dielectric layer 210. The semiconductor layer 220 includes a waveguide region 220A, a transition region 220B and an active component region 220C. A material of the dielectric layer 210 uses silicon dioxide (SiO₂). A material of the semiconductor layer 220 can be a single crystal semiconductor material, such as but not limited to, silicon (Si), germanium (Ge), silicon germanium (SiGe), gallium arsenide (GaAs), indium antimonide (InSb), gallium phosphide (GaP), gallium antimonide (GaSb), aluminum indium arsenide (InAlAs), gallium indium arsenide (InGaAs), gallium antimonide phosphide (GaSbP), gallium antimony arsenide (GaAsSb) and indium phosphide (InP), and the present disclosure uses silicon (Si) as the material of the semiconductor layer 220; preferably, monocrystalline silicon can be used as the material of the semiconductor layer 220.

As shown in FIGS. 3, 4 and 7B, the trench forming step S02 includes etching the semiconductor layer 220 to form a plurality of waveguide trenches T1 in the waveguide region 220A of the semiconductor layer 220, and form a waveguide trench T2 in the transition region 220B of the semiconductor layer 220. In detail, the trench forming step S02 can further include performing a deep etching step S021 and a hydrogen annealing step S022. The deep etching step S021 is performed to perform a deep etching process on the semiconductor layer 220 to form the waveguide trenches T1 in the waveguide region 220A and form the waveguide trench T2 in the transition region 220B so as to pre-define the configuration position of the waveguide structure 110. Further, since the substrate 200 of the present disclosure is a double-layer structure composed of different materials, the etching depths of the waveguide trenches T1 and the waveguide trench T2 can be kept consistent. The hydrogen annealing step S022 is performed to perform a hydrogen annealing process belonging to a low-temperature process on the waveguide trenches T1 and the waveguide trench T2 to eliminate rough surfaces on the sidewalls to smoothen the waveguide trenches T1 and the waveguide trench T2.

As shown in FIGS. 3 and 7C, the waveguide depositing step S03 includes depositing a waveguide material on the semiconductor layer 220 to form a deposition layer 230 on the semiconductor layer 220. The deposition layer 230 covers the waveguide trenches T1 and the waveguide trench T2, that is, the waveguide trenches T1 and the waveguide trench T2 are filled with the waveguide material. The deposition layer 230 can be formed by a Chemical Vapor Deposition (CVD) process, and the aforementioned waveguide material can be silicon nitride (Si₃N₄).

As shown in FIGS. 3, 7C and 7D, the deposition layer polishing step S04 includes performing a Chemical-Mechanical Polishing (CMP) process on the deposition layer 230 to expose a surface 220S in the semiconductor layer 220 and the waveguide material filled in the waveguide trenches T1 and the waveguide trench T2.

As shown in FIGS. 3 and 7E, the ion implanting step S05 includes performing an ion implantation process on the semiconductor layer 220 to form a first doped portion 131 and a second doped portion 133 in the active component region 220C. The first doped portion 131 includes a P-type region 1312 and a heavily doped P-type region 1314, and the second doped portion 133 includes an N-type region 1332 and a heavily doped N-type region 1334. In other embodiments, the ion implanting step of the present disclosure can also be performed after the substrate providing step (i.e., before the trench forming step).

As shown in FIGS. 1, 3, 7E and 7M, the semiconductor layer etching step S06 includes etching the monocrystalline silicon and retaining the waveguide material in the waveguide region 220A to form the waveguide structure 110. The waveguide structure 110 includes the first waveguide portion 111 (of which the cross section of which is shown in FIG. 7M), the directional coupling portion 112 (of which the cross section is shown in FIG. 7M), and the second waveguide portion 113 (shown in FIG. 1). Since the cross section of the second waveguide portion 113 is the same as that of the first waveguide portion 111, the cross section of the second waveguide portion 113 is not shown in FIGS. 7A to 7Q corresponding to the manufacturing method S0. The semiconductor layer etching step S06 can further include partially etching the monocrystalline silicon in the transition region 220B to form the transition structure 120. The transition structure 120 includes a first transition portion 121 and a second transition portion 122 (of which the cross section is shown in FIG. 7M). The semiconductor layer etching step S06 can further include partially etching the first doped portion 131 and the second doped portion 133 located in the active component region 220C to form the active component structure 130 (of which the cross section is shown in FIG. 7M).

As shown in FIGS. 3, 5, 6, 7F and 7G, the semiconductor layer etching step S06 can further include performing a mask disposing step S061, a first etching step S062, a first photoresist forming step S063, a second etching step S064, a second photoresist forming step S065 and a third etching step S066. The mask disposing step S061 includes disposing a hard mask pattern 270H on the surface 220S to expose a first maskless pattern 221; in other words, a part of the semiconductor layer 220 not covered by the hard mask pattern 270H forms the first maskless pattern 221. In detail, the mask disposing step S061 can further include performing a mask depositing step S0611, a photolithography step S0612 and a mask etching step S0613. The mask depositing step S0611 is performed to perform the CVD process on the surface 220S to deposit a dielectric material on the surface 220S to form a hard mask layer 270 on the surface 220S (as shown in FIG. 7F). The aforementioned CVD process can be Plasma-Enhanced Chemical Vapor deposition (PECVD), and the dielectric material can be silicon dioxide (SiO₂). The photolithography step S0612 is performed to perform a photolithography process to form a photomask (not shown) for exposure on the hard mask layer 270. The aforementioned photolithography process can include multiple processes, such as photoresist coating, soft bake, exposure, develop and hard bake, and the photomask is transferred on the hard mask layer 270. The mask etching step S0613 is performed to shield a part of the hard mask layer 270 through the photomask and etch the hard mask layer 270 to form the hard mask pattern 270H (as shown in FIG. 7G).

As shown in FIGS. 5, 7G and 7H, the first etching step S062 is performed to partially etch the first maskless pattern 221 to form a plurality of first etching trenches T3 and the active component structure 130. An etching depth of each of the first etching trenches T3 is the same as each other, and less than or equal to a thickness of the P-type region 1312 (i.e., a thickness of the N-type region 1332) of the active component structure 130.

As shown in FIGS. 5 and 7I, the first photoresist forming step S063 is performed to form a first photoresist layer 290a having patterned on a part of the transition region 220B and a part of the active component region 220C to expose a second maskless pattern 222 via photoresist coating (e.g., spin coating); in other words, the part of the semiconductor layer 220 not covered by the hard mask pattern 270H and the first photoresist layer 290a forms the second maskless pattern 222.

As shown in FIGS. 5 and 7J, the second etching step S064 is performed to etch the second maskless pattern 222 to form a plurality of second etching trenches T4 and the first transition portion 121 and the second transition portion 122 of the transition structure 120. An etching depth of each of the second etching trenches T4 is the same as each other, and the first etching trenches T3 and the second etching trenches T4 can be produced by an isotropic etching process.

As shown in FIGS. 5, 7K and 7L, the second photoresist forming step S065 is performed to remove the first photoresist layer 290a and the hard mask pattern 270H and form a second photoresist layer 290b on the transition structure 120 and the active component structure 130 to shield the transition structure 120 and the active component structure 130.

As shown in FIGS. 5, 7L and 7M, the third etching step S066 is performed to etch a third maskless pattern 223 (i.e., the monocrystalline silicon surrounding the waveguide material in the waveguide region 220A) not shielded by the second photoresist layer 290b to form the first waveguide portion 111, the directional coupling portion 112 and the second waveguide portion 113 (as shown in FIG. 1) of the waveguide structure 110. The etching process in the third etching step S066 can be an anisotropic etching process.

As shown in FIGS. 3 and 7N, the cover layer depositing step S07 includes depositing a cover layer 240 on the dielectric layer 210. The cover layer 240 covers the waveguide structure 110, the transition structure 120 and the active component structure 130, and a material of the cover layer 240 can be the same as that of the dielectric layer 210.

As shown in FIGS. 3 and 7O to 7Q, the via hole and contact pad forming step S08 includes forming two via holes 250 connected to the active component structure 130 in the cover layer 240, and respectively forming two contact pads 260 on the two via holes 250. In detail, the via hole and contact pad forming step S08 is performed to perform an etching process on the cover layer 240 to form the two via holes 250 on the heavily doped P-type region 1314 and the heavily doped N-type region 1334 (as shown in FIG. 7O.). In addition, Tungsten is deposited on the cover layer 240 through the CVD process or a Physical vapor deposition (PVD), so that the two via holes 250 are filled with Tungsten to form a conductive channel, and then the CMP process is performed to remove Tungsten on the cover layer 240. After that, a conductive material (e.g., AlCu) is deposited on the cover layer 240, and then the photolithography process is performed to form the two contact pads 260 on the two via holes 250 (as shown in FIG. 7P). Depositing the same optical cladding material as the cover layer 240 to cover the two contact pads 260 at last, and performing the etching process to respectively form two openings 280 (as shown in FIG. 7Q) on the two contact pads 260, so that the external circuits are electrically connected to the two contact pads 260.

Different from the existing waveguide manufacturing method, the manufacturing method S0 of the present disclosure is to directly etch the semiconductor layer 220 to pre-define the configuration position of the waveguide structure 110, use the ion implantation process to define the configuration position of the active component structure 130, use the first photoresist layer 290a and the second photoresist layer 290b to be an etching mask to perform the etching process to form the waveguide structure 110, the transition structure 120 and the active component structure 130, and complete the metal connecting through the semiconductor back-end processes at last, thereby manufacturing the integrated structure 100 of the waveguide and the active component with high light coupling efficiency. Thus, the waveguide structure 110, the transition structure 120 and the active component structure 130 connected to each other in sequence can be disposed between the dielectric layer 210 and the cover layer 240 via the above steps of the manufacturing method S0 of the present disclosure. Since the waveguide structure 110, the transition structure 120 and the active component structure 130 are disposed on the dielectric layer 210 and located in the cover layer 240, the light coupling efficiency of the integrated structure 100 of the waveguide and the active component is higher.

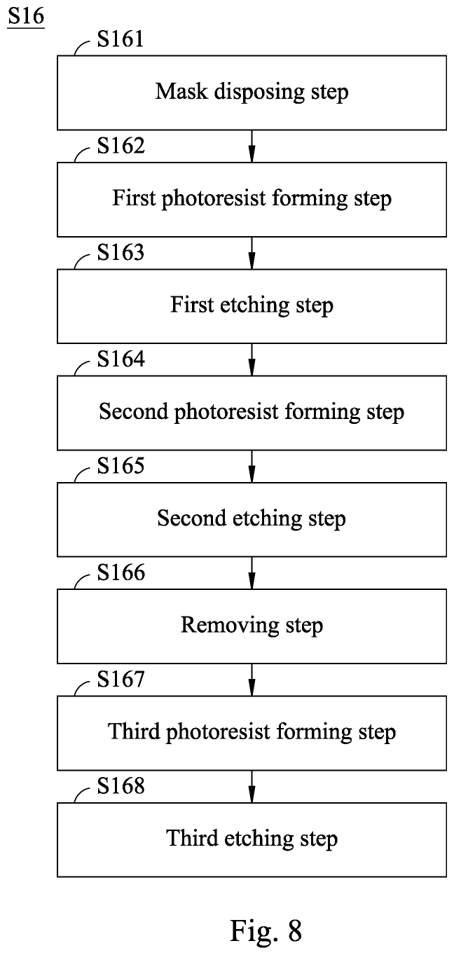

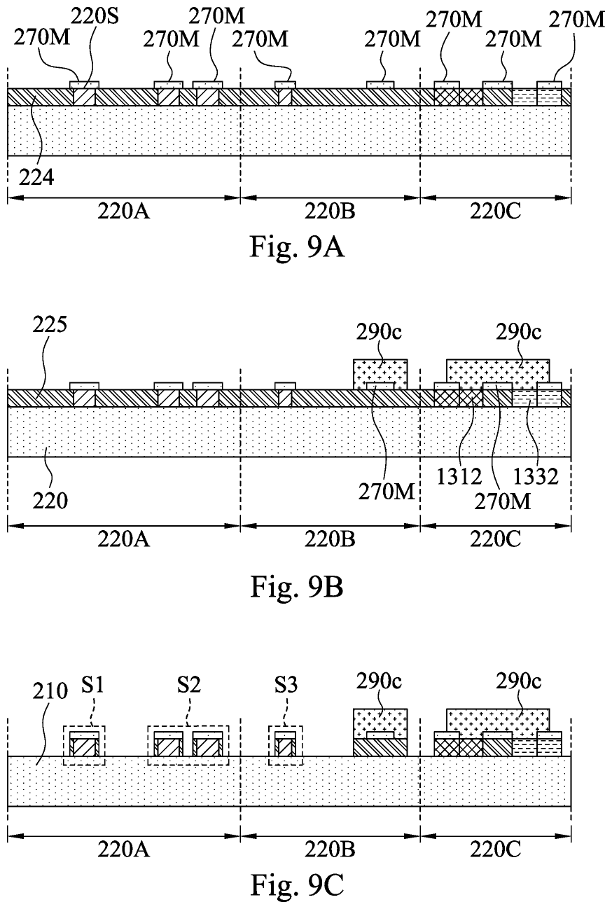

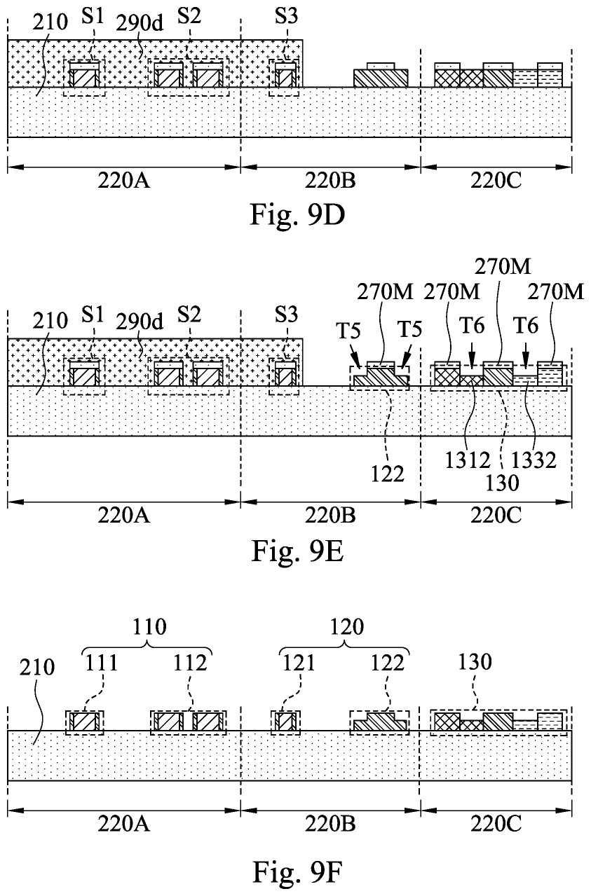

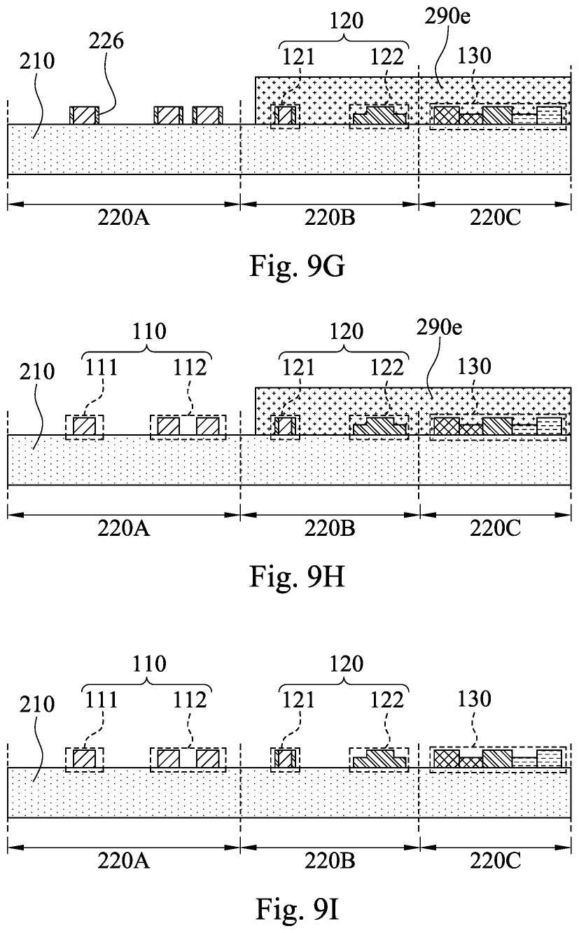

Please refer to FIGS. 8, 9A, 9B, 9C, 9D, 9E, 9F, 9G, 9H and 9I. FIG. 8 shows a flow chart of a semiconductor layer etching step S16 of a manufacturing method of the integrated structure of the waveguide and the active component (hereinafter referred to as the manufacturing method) according to a third embodiment of the present disclosure. FIG. 9A is a cross-sectional view of a mask disposing step S161 of the semiconductor layer etching step S16 of the manufacturing method according to the third embodiment of the present disclosure. FIG. 9B shows a cross-sectional view of a first photoresist forming step S162 of the semiconductor layer etching step S16 of the manufacturing method of the third embodiment. FIG. 9C shows a cross-sectional view of a first etching step S163 of the semiconductor layer etching step S16 of the manufacturing method of the third embodiment. FIG. 9D shows a cross-sectional view of a second photoresist forming step S164 of the semiconductor layer etching step S16 of the manufacturing method of the third embodiment. FIG. 9E shows a cross-sectional view of a second etching step S165 of the semiconductor layer etching step S16 of the manufacturing method of the third embodiment. FIG. 9F shows a cross-sectional view of removing a photoresist and a hard mask in a removing step S166 of the semiconductor layer etching step S16 of the manufacturing method of the third embodiment. FIG. 9G shows a cross-sectional view of a third photoresist forming step S167 of the semiconductor layer etching step S16 of the manufacturing method of the third embodiment. FIG. 9H shows a cross-sectional view of a third etching step S168 of the semiconductor layer etching step S16 of the manufacturing method of the third embodiment. FIG. 9I shows another cross-sectional view of the third etching step S168 of the semiconductor layer etching step S16 of the manufacturing method of the third embodiment.

The manufacturing method of the third embodiment can also be configured to manufacture the integrated structure 100 of the waveguide and the active component, and includes performing a substrate providing step, a trench forming step, a waveguide depositing step, a deposition layer polishing step, an ion implanting step, the semiconductor layer etching step S16, a cover layer depositing step and a via hole and contact pad forming step. Except for the semiconductor layer etching step S16, the other steps of the manufacturing method of the third embodiment are the same as the steps corresponding to the manufacturing method S0 of the second embodiment, and not be described again herein.

As shown in FIG. 8, the semiconductor layer etching step S16 can further include performing the mask disposing step S161, the first photoresist forming step S162, the first etching step S163, the second photoresist forming step S164, the second etching step S165, the removing step S166, the third photoresist forming step S167 and the third etching step S168.

As shown in FIG. 9A, the mask disposing step S161 is performed to dispose a hard mask pattern 270M on the surface 220S to expose a first maskless pattern 224. The forming method of the hard mask pattern 270M is the same as that of the hard mask pattern 270H, and not be described again herein.

As shown in FIG. 9B, the first photoresist forming step S162 is performed to form a first photoresist layer 290c on a part of the transition region 220B and a part of the active component region to expose a second maskless pattern 225 via photoresist coating (e.g., spin coating); in other words, the part of the semiconductor layer 220 not covered by the hard mask pattern 270M and the first photoresist layer 290c forms the second maskless pattern 225, and the second maskless pattern 225 is a part of the first maskless pattern 224.

As shown in FIG. 9C, the first etching step S163 is performed to etch the second maskless pattern 225 so as to remove the monocrystalline silicon not shielded by the hard mask pattern 270M and the first photoresist layer 290c completely to form a plurality of etching trenches (not shown) with the same etching depth and expose a first initial structure S1, a second initial structure S2 and a third initial structure S3 on the dielectric layer 210.

As shown in FIG. 9D, the second photoresist forming step S164 is performed to remove the first photoresist layer 290c and form a second photoresist layer 290d on the dielectric layer 210 to clad/cover the first initial structure S1, the second initial structure S2 and the third initial structure S3 via photoresist coating.

As shown in FIG. 9E, the second etching step S165 is performed to partially etch the part of the transition region 220B not shielded by the second photoresist layer 290d and the hard mask pattern 270M to form a plurality of first etching trenches T5 and the second transition portion 122 of the transition structure 120, and partially etch the part of the active component region 220C not shielded by the second photoresist layer 290d and the hard mask pattern 270M to form a plurality of second etching trenches T6 and the active component structure 130. An etching depth of each of the first etching trenches T5 is the same as an etching depth of each of the second etching trenches T6, and less than or equal to a thickness of the P-type region 1312 (i.e., a thickness of the N-type region 1332) of the active component structure 130.

As shown in FIG. 9F, the removing step S166 is performed to remove the second photoresist layer 290d and the hard mask pattern 270M to form and expose the first transition portion 121 and the second transition portion 122 of the transition structure 120 and the active component structure 130 on the dielectric layer 210.

As shown in FIGS. 9G, 9H and 9I, the third photoresist forming step S167 is performed to form a third photoresist layer 290e on the transition structure 120 and the active component structure 130 to shield the transition structure 120 and the active component structure 130 via photoresist coating. The third etching step S168 is performed to etch a third maskless pattern 226 (i.e., the monocrystalline silicon surrounding the waveguide material in the waveguide region 220A) not shielded by the third photoresist layer 290e to form the first waveguide portion 111, the directional coupling portion 112 and the second waveguide portion 113 (as shown in FIG. 1) of the waveguide structure 110, and remove the third photoresist layer 290e to expose the first transition portion 121 and the second transition portion 122 of the transition structure 120 and the active component structure 130. The etching process in the first etching step S163 and the second etching step S165 can be the isotropic etching process, and the etching process in the third etching step S168 can be the anisotropic etching process.

Therefore, the waveguide structure 110, the transition structure 120 and the active component structure 130 in the semiconductor layer etching step S16 of the present disclosure can be constructed by using the first photoresist layer 290c, the second photoresist layer 290d and the third photoresist layer 290e with the isotropic/anisotropic etching process.

According to the aforementioned embodiments and examples, the advantages of the present disclosure are described as follows.
1. Active and passive optical elements of semiconductor materials and dielectric materials can be integrated into the same layer structure (that is, the dielectric layer) without epitaxy, and located in another layer structure (that is, the cover layer), so the light coupling efficiency is higher.
2. Low-loss and anomalous-dispersion silicon nitride waveguides can be fabricated, so the present disclosure can be applied to low-loss photonic integrated circuits, visible photonic integrated circuits and nonlinear optical resonance cavities.
3. The present disclosure is compatible with the current CMOS process and has mass production capability.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An integrated structure of a waveguide and an active component, comprising:
a dielectric layer;
a waveguide structure disposed on the dielectric layer;
a transition structure disposed on the dielectric layer and connected to the waveguide structure;
an active component structure disposed on the dielectric layer and connected to the transition structure;
a cover layer disposed on the dielectric layer and covering the waveguide structure, the transition structure and the active component structure;
two via holes located in the cover layer and connected to the active component structure; and
two contact pads located in the cover layer and respectively disposed on the two via holes.

2. The integrated structure of the waveguide and the active component of claim 1, wherein the waveguide structure, the transition structure and the active component structure are disposed between the dielectric layer and the cover layer, and connected to each other in sequence.

3. The integrated structure of the waveguide and the active component of claim 1, wherein the transition structure comprises:
a first transition portion, comprising:
a waveguide connecting sub-portion, wherein one end of the waveguide connecting sub-portion is connected to the waveguide structure; and
a semiconductor connecting sub-portion connected to and surrounding another end of the waveguide connecting sub-portion; and
a second transition portion connected between the semiconductor connecting sub-portion and the active component structure, wherein a cross section of the second transition portion is formed in a protruded shape.

4. The integrated structure of the waveguide and the active component of claim 1, wherein a material of the dielectric layer and the cover layer is silicon dioxide (SiO₂).

5. The integrated structure of the waveguide and the active component of claim 1, wherein the waveguide structure is composed of a waveguide material, and the waveguide material is silicon nitride (Si₃N₄).

6. A manufacturing method of an integrated structure of a waveguide and an active component, comprising:
performing a substrate providing step comprising providing a substrate, wherein the substrate comprises a dielectric layer and a semiconductor layer disposed on the dielectric layer, and the semiconductor layer comprises a waveguide region, a transition region and an active component region;
performing a trench forming step comprising etching the semiconductor layer to form a plurality of waveguide trenches in the waveguide region and the transition region of the semiconductor layer;
performing a waveguide depositing step comprising depositing a waveguide material on the semiconductor layer to form a deposition layer on the semiconductor layer, wherein the waveguide trenches are filled with the waveguide material;
performing a deposition layer polishing step comprising performing a chemical-mechanical polishing process on the deposition layer to expose a surface in the semiconductor layer and the waveguide material filled in the waveguide trenches;
performing an ion implanting step comprising performing an ion implantation process on the semiconductor layer to form a first doped portion and a second doped portion in the active component region;
performing a semiconductor layer etching step comprising:
etching the waveguide region to form a waveguide structure;
etching the transition region to form a transition structure; and
etching the first doped portion and the second doped portion to form an active component structure;
performing a cover layer depositing step comprising depositing a cover layer on the dielectric layer, wherein the cover layer covers the waveguide structure, the transition structure and the active component structure; and
performing a via hole and contact pad forming step comprising forming two via holes connected to the active component structure in the cover layer, and respectively forming two contact pads on the two via holes.

7. The manufacturing method of the integrated structure of the waveguide and the active component of claim 6, wherein the trench forming step further comprises:
performing a deep etching step to perform a deep etching process on the semiconductor layer to form the waveguide trenches in the waveguide region and the transition region of the semiconductor layer; and
performing a hydrogen annealing step to perform a hydrogen annealing process on the waveguide trenches to smoothen the waveguide trenches.

8. The manufacturing method of the integrated structure of the waveguide and the active component of claim 6, wherein the semiconductor layer etching step further comprises:
performing a mask disposing step comprising disposing a hard mask pattern on the surface to expose a first maskless pattern;
performing a first etching step to partially etch the first maskless pattern to form a plurality of first etching trenches and the active component structure, wherein an etching depth of each of the first etching trenches is the same as each other;
performing a first photoresist forming step to form a first photoresist layer on a part of the transition region and a part of the active component region to expose a second maskless pattern;
performing a second etching step to etch the second maskless pattern to form a plurality of second etching trenches and the transition structure, wherein an etching depth of each of the second etching trenches is the same as each other;
performing a second photoresist forming step to remove the first photoresist layer and the hard mask pattern and form a second photoresist layer on the transition structure and the active component structure to shield the transition structure and the active component structure; and
performing a third etching step to etch a third maskless pattern not shielded by the second photoresist layer to form the waveguide structure.

9. The manufacturing method of the integrated structure of the waveguide and the active component of claim 8, wherein the mask disposing step further comprises:
performing a mask depositing step to deposit a dielectric material on the surface to form a hard mask layer on the surface;
performing a photolithography step to perform a photolithography process to form a photomask on the hard mask layer; and
performing a mask etching step to shield a part of the hard mask layer through the photomask and etch the hard mask layer to form the hard mask pattern.

10. The manufacturing method of the integrated structure of the waveguide and the active component of claim 6, wherein the semiconductor layer etching step further comprises:
performing a mask disposing step to dispose a hard mask pattern on the surface to expose a first maskless pattern;
performing a first photoresist forming step to form a first photoresist layer on a part of the transition region and a part of the active component region to expose a second maskless pattern, wherein the second maskless pattern is a part of the first maskless pattern;
performing a first etching step to etch the second maskless pattern to form a plurality of etching trenches and expose a first initial structure, a second initial structure and a third initial structure on the dielectric layer;
performing a second photoresist forming step to remove the first photoresist layer and form a second photoresist layer on the dielectric layer to cover the first initial structure, the second initial structure and the third initial structure;
performing a second etching step to partially etch the part of the transition region not shielded by the second photoresist layer and the hard mask pattern to form a plurality of first etching trenches and the transition structure, and partially etch the part of the active component region not shielded by the second photoresist layer and the hard mask pattern to form a plurality of second etching trenches and the active component structure;
performing a removing step to remove the second photoresist layer and the hard mask pattern to form and expose a first transition portion and a second transition portion of the transition structure and the active component structure on the dielectric layer;
performing a third photoresist forming step to form a third photoresist layer on the transition structure and the active component structure to shield the transition structure and the active component structure; and
performing a third etching step to etch a third maskless pattern not shielded by the third photoresist layer to form the waveguide structure and remove the third photoresist layer to expose the first transition portion and the second transition portion of the transition structure and the active component structure.

11. The manufacturing method of the integrated structure of the waveguide and the active component of claim 6, wherein the waveguide structure, the transition structure and the active component structure are disposed between the dielectric layer and the cover layer, and connected to each other in sequence.

12. The manufacturing method of the integrated structure of the waveguide and the active component of claim 6, wherein a material of the semiconductor layer is silicon, and a material of the dielectric layer and the cover layer is silicon dioxide (SiO₂).

13. The manufacturing method of the integrated structure of the waveguide and the active component of claim 6, wherein the deposition layer is formed by a Chemical Vapor Deposition (CVD) process, and the waveguide material is silicon nitride (Si₃N₄).
